(19) United States
(12) Patent Application Publication
(10) Pub. No.: US 2025/0105139 A1
(43) Pub. Date: Mar. 27, 2025

(54) INTEGRATED CIRCUIT STRUCTURES WITH VIAS CONNECTED TO BONDING PADS

(71) Applicant: Intel Corporation, Santa Clara, CA (US)

(72) Inventor: Abhishek A. Sharma, Portland, OR (US)

(73) Assignee: Intel Corporation, Santa Clara, CA (US)

(21) Appl. No.: 18/473,387

(22) Filed: Sep. 25, 2023

(51) Int. Cl. H01L 23/522; H01L 23/00

(52) U.S. Cl. CPC H01L 23/5226; H01L 24/05; H01L 24/08; H01L 2224/05556; H01L 2224/08145; H01L 2224/08225

(57) ABSTRACT

An example IC structure includes a first layer comprising a plurality of transistors; a second layer comprising a stack of layers of one or more insulator materials and conductive interconnect structures extending through the one or more insulator materials; a third layer comprising bonding pads, wherein the second layer is between the first layer and the third layer; and a via continuously extending between one of the bonding pads and one of the conductive interconnect structures in a bottom layer of the stack of layers or a conductive structure in the first layer, wherein the bottom layer is a layer of the stack of layers that is closer to the first layer than all other layers of the stack of layers.

### BACKGROUND

For the past several decades, the scaling of features in integrated circuits has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for the ever-increasing capacity, however, is not without issue. The necessity to optimize the performance of each device and each interconnect becomes increasingly significant.

### BRIEF DESCRIPTION OF THE DRAWINGS

Embodiments will be readily understood by the following detailed description in conjunction with the accompanying drawings.

FIGS. 1A-1B provide block diagrams of integrated circuit (IC) structures in which vias connected to bonding pads may be included, according to some embodiments of the present disclosure.

FIGS. 2A-2H illustrate cross-sectional side views of example IC structures with vias connected to bonding pads, according to some embodiments of the present disclosure.

FIG. 3 illustrates top views of a wafer and dies that may include an IC structure with one or more vias connected to bonding pads in accordance with any of the embodiments disclosed herein.

FIG. 4 is a cross-sectional side view of an IC package that may include an IC structure with one or more vias connected to bonding pads in accordance with any of the embodiments disclosed herein.

FIG. 5 is a cross-sectional side view of an IC device assembly that may include an IC structure with one or more vias connected to bonding pads in accordance with any of the embodiments disclosed herein.

FIG. 6 is a block diagram of an example computing device that may include an IC structure with one or more vias connected to bonding pads in accordance with any of the embodiments disclosed herein.

FIG. 7 is a block diagram of an example processing device that may include an IC structure with one or more vias connected to bonding pads in accordance with any of the embodiments disclosed herein.

### DETAILED DESCRIPTION

The systems, methods and devices of this disclosure each have several innovative aspects, no single one of which is solely responsible for all of the desirable attributes disclosed herein. Details of one or more implementations of the subject matter described in this specification are set forth in the description below and the accompanying drawings.

For purposes of illustrating IC structures with vias connected to bonding pads as described herein, it might be useful to first understand phenomena that may come into play in certain IC arrangements. The following foundational information may be viewed as a basis from which the present disclosure may be properly explained. Such information is offered for purposes of explanation only and, accordingly, should not be construed in any way to limit the broad scope of the present disclosure and its potential applications.

IC fabrication usually includes two stages. The first stage is referred to as the front-end of line (FEOL). The second stage is referred to as the back-end of line (BEOL). In the FEOL, individual semiconductor device components (e.g., transistor, capacitors, resistors, etc.) can be patterned in a wafer. In the BEOL, interconnect structures such as conductive lines and conductive vias, separated as needed by an insulator material, can be formed to get the individual components interconnected. The BEOL usually starts with forming the first metal layer on the wafer. The first metal layer is often called M0. More metal layers can be formed on top of M0, and these metal layers are often called M1, M2, and so on. Optionally, additional semiconductor device components may be provided in the BEOL, e.g., decoupling capacitors, backend transistors, etc.

Once all the metal layers of the BEOL have been formed, bonding pads (e.g., high-bandwidth interconnect (HBI) bonding pads) may be formed on top of the metal layers. The bonding pads may be electrically coupled with the interconnect structures of the BEOL and configured to route the electrical signals of the semiconductor device components of the FEOL, and possibly those of the BEOL, to other external devices. For example, solder bonds may be formed on the one or more bonding pads to mechanically and/or electrically couple a chip including an IC structure with the FEOL and BEOL as described above with another component (e.g., a circuit board, a package substrate, an interposer, or another die/chip).

A pitch of the bonding pads is typically much larger than a pitch of interconnect structures in the FEOL or the BEOL layers. As used herein, pitch is measured center-to-center (e.g., from the center of a bonding pad to the center of an adjacent bonding pad). For example, a pitch of the bonding pads at the top of the metal layers of the BEOL may be on the order of about 10 to 20 micron, while a pitch of the interconnect structures in the lower layers of the BEOL may be below about 0.5 micron, e.g., it may be on the order of about 100 nanometers. Therefore, one or more redistribution layers (RDLs) are typically provided between the top of the metal layers of the BEOL and the bonding pads. RDLs help redistribute the input/output (I/O) connections from the IC's core (e.g., from the semiconductor device components of the FEOL) to the external connectors or to other components within an IC package. To that end, RDLs may include multiple additional metal layers (in addition to those of the BEOL) with interconnect structures that are used for routing signals, ground, and power to and from the chip.

Embodiments of the present disclosure are based on recognition that providing one or more RDLs between the top of the BEOL and the bonding pads may have disadvantages in terms of, e.g., energy consumption or delay in signal propagation. To improve on these, IC structures that include one or more vias that connect one or more electrical components of the FEOL and/or the BEOL (e.g., one or more terminals of semiconductor device components in the FEOL or the BEOL, or any of the interconnect structures of the FEOL or the BEOL) to one or more bonding pads are disclosed. As used herein, a via may be described as “being connected” to a bonding pad if an electrically conductive material of the via is in conductive contact (e.g., in direct physical contact) with an electrically conductive material of a bonding pad. This is in sharp difference to a via being connected to an RDL, and then the RDL providing further connectivity to the bonding pad. An example IC structure includes a first layer comprising a plurality of transistors; a second layer comprising a stack of layers of one or more insulator materials and conductive interconnect structures extending through the one or more insulator materials; a third layer comprising bonding pads, wherein the second layer is between the first layer and the third layer; and a via continuously extending between one of the bonding pads and one of the conductive interconnect structures in a bottom layer of the stack of layers or a conductive structure in the first layer, wherein the bottom layer is a layer of the stack of layers that is closer to the first layer than all other layers of the stack of layers.

Various IC structures with vias connected to bonding pads as described herein may be implemented in, or associated with, one or more components associated with an IC or/and may be implemented between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

In the following detailed description, various aspects of the illustrative implementations may be described using terms commonly employed by those skilled in the art to convey the substance of their work to others skilled in the art. For example, the term “connected” means a direct electrical or magnetic connection between the things that are connected, without any intermediary devices, while the term “coupled” means either a direct electrical or magnetic connection between the things that are connected, or an indirect connection through one or more passive or active intermediary devices. The term “circuit” means one or more passive and/or active components that are arranged to cooperate with one another to provide a desired function. If used, the terms “oxide,” “carbide,” “nitride,” etc. refer to compounds containing, respectively, oxygen, carbon, nitrogen, etc., the term “high-k dielectric” refers to a material having a higher dielectric constant (k) than silicon oxide, while the term “low-k dielectric” refers to a material having a lower k than silicon oxide. Although certain elements may be referred to in the singular herein, such elements may include multiple sub-elements. For example, “an insulator material” may include one or more insulator materials. The term “insulating” and variations thereof (e.g., “insulative” or “insulator”) means “electrically insulating,” the term “conducting” and variations thereof (e.g., “conductive” or “conductor”) means “electrically conducting,” unless otherwise specified. For example, the term “insulating material” refers to solid materials (and/or liquid materials that solidify after processing as described herein) that are substantially electrically nonconducting. They may include, as examples and not as limitations, organic polymers and plastics, and inorganic materials such as ionic crystals, porcelain, glass, silicon and alumina or a combination thereof. They may include dielectric materials, high polarizability materials, and/or piezoelectric materials. They may be transparent or opaque without departing from the scope of the present disclosure. With reference to optical signals and/or devices, components and elements that operate on or using optical signals, the term “conducting” can also mean “optically conducting.”

In the following detailed description, reference is made to the accompanying drawings that form a part hereof wherein like numerals designate like parts throughout, and in which is shown, by way of illustration, embodiments that may be practiced. It is to be understood that other embodiments may be utilized, and structural or logical changes may be made, without departing from the scope of the present disclosure. Therefore, the following detailed description is not to be taken in a limiting sense.

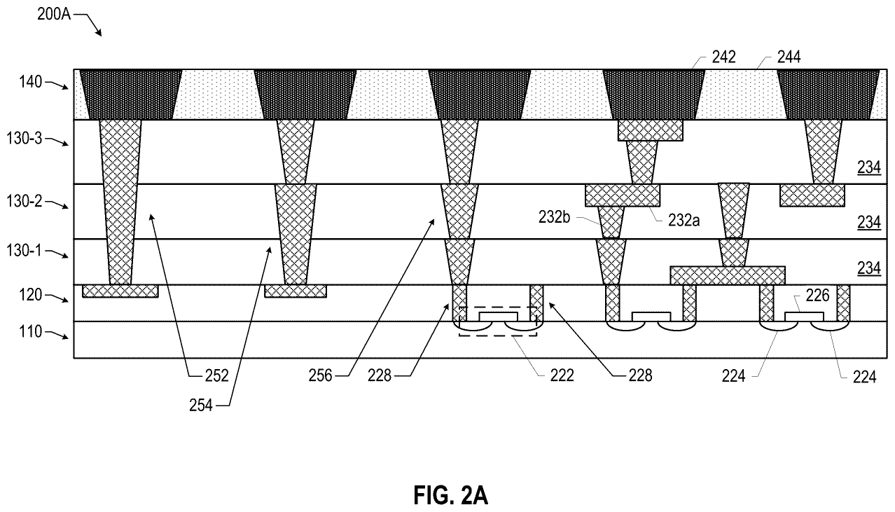

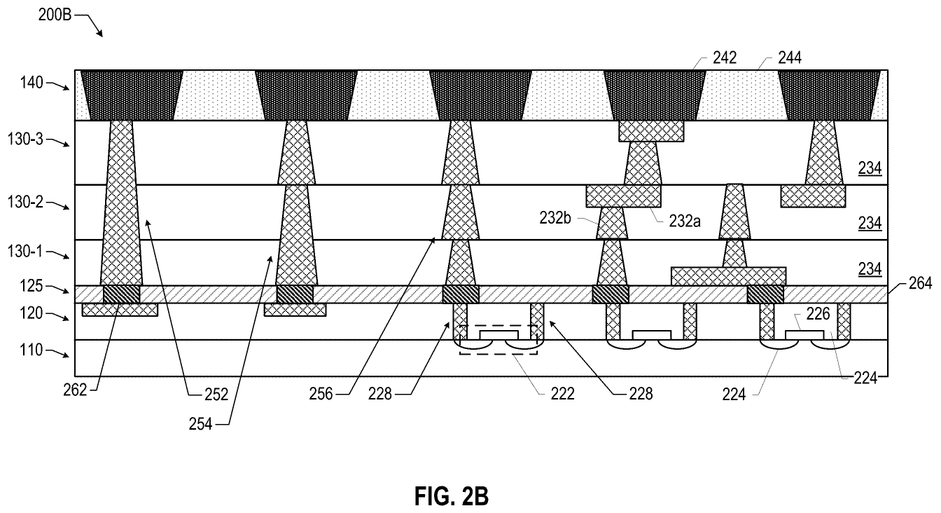

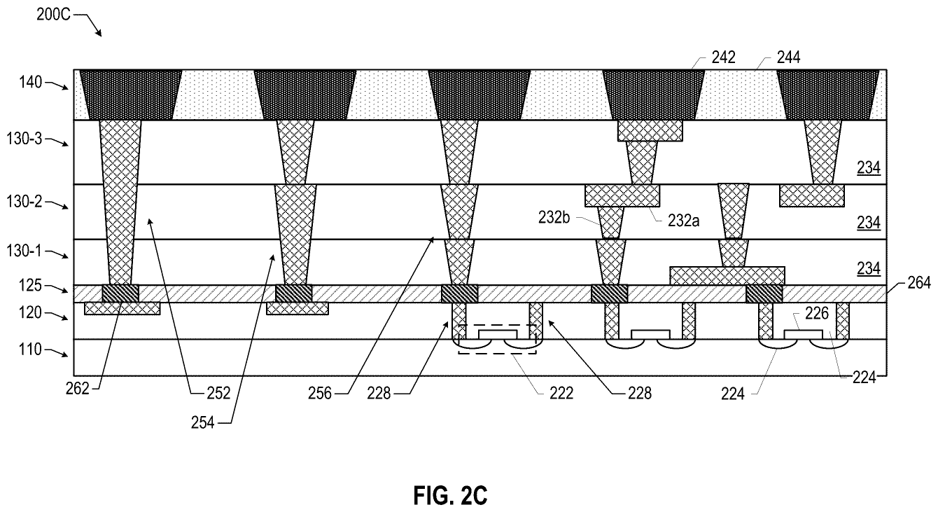

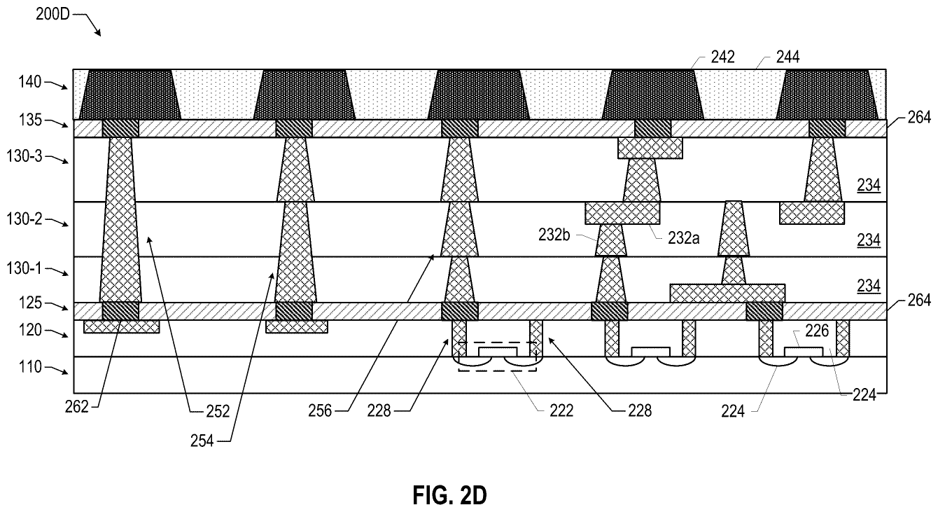

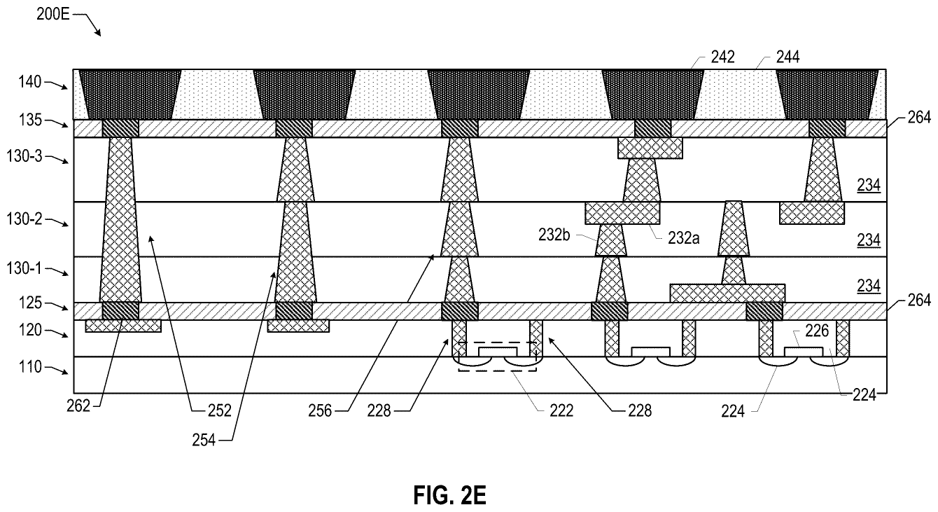

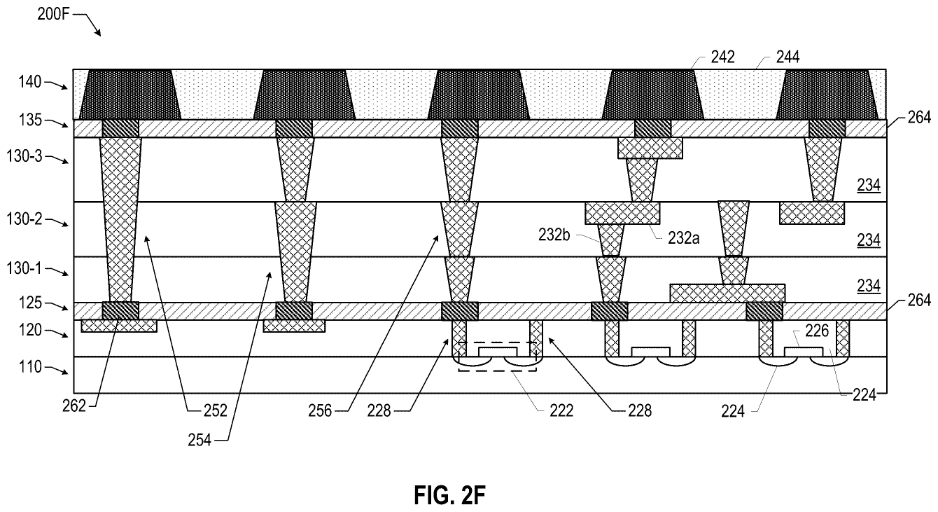

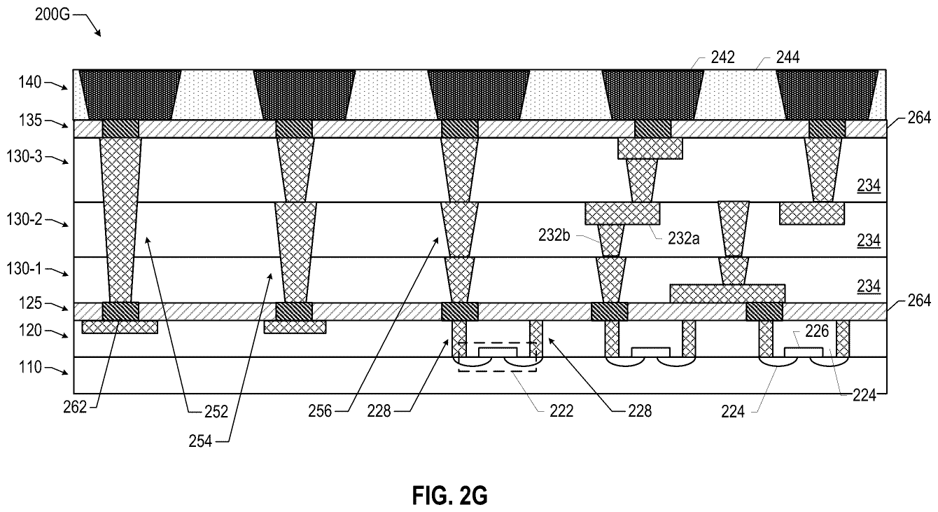

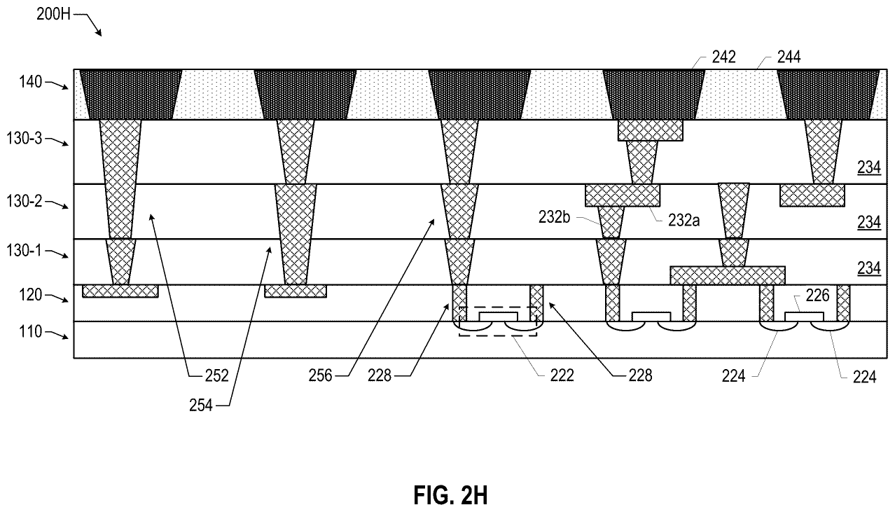

Any of the features discussed with reference to any of accompanying drawings herein may be combined with any other features to form IC structures with vias connected to bonding pads, as appropriate. A number of elements of the drawings are shared with others of the drawings; for ease of discussion, a description of these elements is not repeated, and these elements may take the form of any of the embodiments disclosed herein. If multiple instances of certain elements are illustrated, then, in some cases, to not clutter the drawings only some of these elements may be labeled with a reference sign and other ones of these elements are not labeled (e.g., although FIG. 2A illustrates multiple conductive lines 232a, only one of them is labeled with a reference sign). However, in other cases, for ease of explanation, different instances of a given element in a single drawing may be referred to with numbers 1, 2, and so on, after a dash (e.g., FIG. 2A illustrates multiple metal layers 130, labeled individually as metal layers 130-1, 130-2, and 130-3), or with different letters after the reference numerals (e.g., FIG. 2A illustrates an IC structure 200A, FIG. 2B illustrates an IC structure 200B, and so on).

The drawings are not necessarily to scale. Although many of the drawings illustrate rectilinear structures with flat walls and right-angle corners, this is simply for ease of illustration and may not reflect real-life process limitations which may cause various features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of an IC structure using e.g., optical microscopy, TEM, or SEM, and/or inspection of a cross-section of an IC structure to detect the shape and the location of various device elements described herein using, e.g., Physical Failure Analysis (PFA) would allow determination of presence of vias connected to bonding pads as described herein

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). When used to describe a range of dimensions, the phrase “between X and Y” represents a range that includes X and Y. When used to describe a location of an element, the phrase “between X and Y” represents a region that is spatially between element X and element Y. The description may use the phrases “in an embodiment” or “in embodiments,” which may each refer to one or more of the same or different embodiments. The terms “substantially,” “close,” “approximately,” “near,” and “about,” generally refer to being within +/−20%, e.g., within +/−5% or within +/−2%, of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−20%, e.g., within +/−5% or within +/−2%, of a target value based on the context of a particular value as described herein or as known in the art.

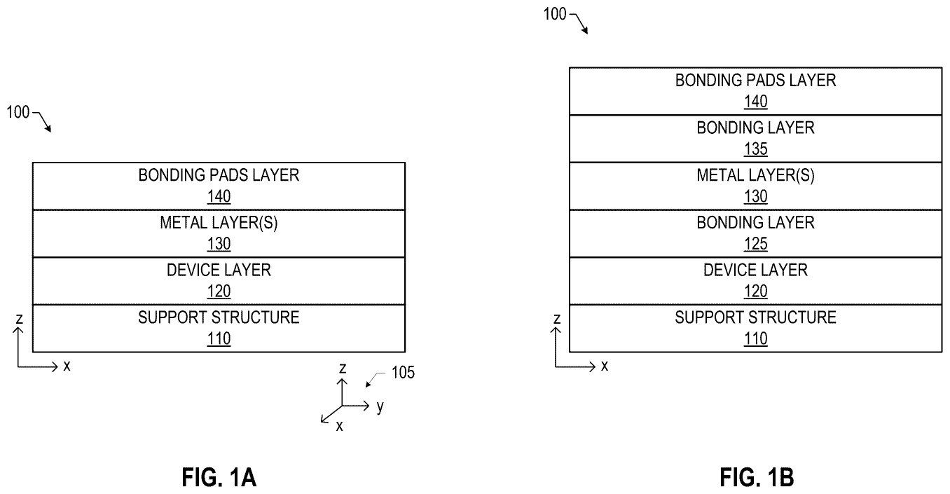

FIGS. 1A-1B provide block diagrams of IC structures 100 in which one or more vias connected to bonding pads may be included, according to some embodiments of the present disclosure. The illustrations of FIGS. 1A-1B are intended to provide a general orientation and arrangement of various layers with respect to one another. FIG. 1A illustrates an example coordinate system 105 with axes x-y-z so that the various planes illustrated in FIG. 1A and in some subsequent drawings may be described with reference to this coordinate system. Unless specified otherwise in the present disclosure, illustrations of FIGS. 1A-1B are intended to cover embodiments of the IC structures 100 where portions of elements described with respect to one of the layers shown in FIGS. 1A-1B may extend into one or more, or be present in, other layers. Some example implementation of the IC structure 100 of FIG. 1A is an IC structure 200A, shown in FIG. 2A, and an IC structure 200H, shown in FIG. 2H, and described below. Some example implementations of the IC structure 100 of FIG. 1B are IC structures 200B-200G, shown in FIGS. 2B-2G and described below.

As shown in FIG. 1A, in general, the IC structure 100 may include a device layer 120, one or more metal layers 130, and a bonding pads layer 140. In some embodiments, the IC structure 100 may also include a support structure 110; although, in other embodiments, the support structure 110 may be absent (e.g., the support structure 110 may be removed after the device layer 120 has been built thereon, e.g., to allow electrical connectivity from the back side of the device layer 120).

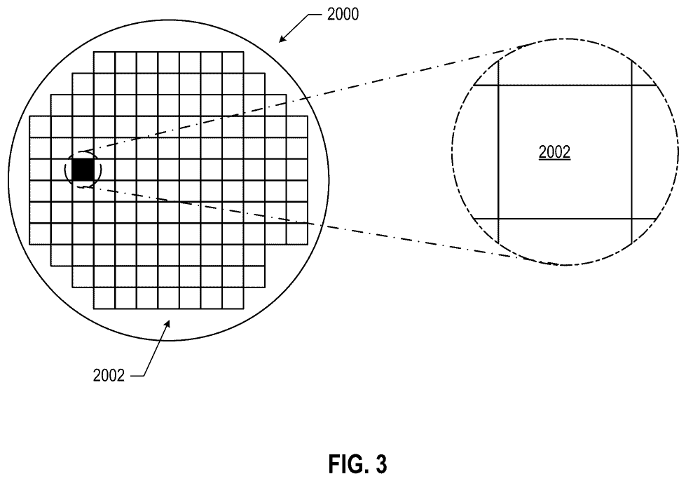

The support structure 110 may be any suitable support over which the device layer 120 may be provided. For example, the support structure 110 may be a substrate, a die, a wafer or a chip. The support structure 110 may, e.g., be the wafer 2000 of FIG. 3, discussed below, and may be, or be included in, a die, e.g., the singulated die 2002 of FIG. 3, discussed below. The support structure 110 may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline. In some embodiments, the support structure 110 may be a printed circuit board (PCB) substrate. In some embodiments, the support structure 110 may be a glass core. As used herein, the term “glass core” refers to a structure (e.g., a portion of a glass layer) of any glass material such as quartz, silica, fused silica, silicate glass (e.g., borosilicate, aluminosilicate, alumino-borosilicate), soda-lime glass, soda-lime silica, borofloat glass, lead borate glass, photosensitive glass, non-photosensitive glass, or ceramic glass. In particular, a glass core may be bulk glass or a solid volume/layer of glass, as opposed to, e.g., materials that may include particles of glass, such as glass fiber reinforced polymers. Such glass materials are typically non-crystalline, often transparent, amorphous solids. In some embodiments, a glass core may be an amorphous solid glass layer. In some embodiments, a glass core may include silicon and oxygen, as well as any one or more of aluminum, boron, magnesium, calcium, barium, tin, sodium, potassium, strontium, phosphorus, zirconium, lithium, titanium, and zinc. In some embodiments, a glass core may include a material, e.g., any of the materials described above, with a weight percentage of silicon being at least about 0.5%, e.g., between about 0.5% and 50%, between about 1% and 48%, or at least about 23%. For example, if a glass core is fused silica, the weight percentage of silicon may be about 47%. In some embodiments, a glass core may include at least 23% silicon and/or at least 26% oxygen by weight, and, in some further embodiments, a glass core may further include at least 5% aluminum by weight. In some embodiments, a glass core may include any of the materials described above and may further include one or more additives such as Al2O3, B203, MgO, CaO, SrO, BaO, SnO2, Na2O, K2O, SrO, P2O3, ZrO2, Li2O, Ti, and Zn. In some embodiments, a glass core may be a layer of glass that does not include an organic adhesive or an organic material. In some embodiments, a cross-section of the support structure 110 in an x-z plane, a y-z plane, and/or an x-y plane of the coordinate system 105 shown in FIG. 1A may be substantially rectangular. Although a few examples of materials from which the substrate may be formed are described here, any material that may serve as a foundation upon which an IC structure with one or more vias connected to bonding pads as described herein may be built falls within the spirit and scope of the present disclosure.

The device layer 120 may include any combination of active ICs of semiconductor device components provided over the support structure 110. For example, in some embodiments, the device layer 120 may include various logic layers, circuits, and devices (e.g., logic transistors) to drive and control a logic IC. In some embodiments, the device layer 120 may include memory devices/circuits.

The metal layers 130 may be, or include, metal layers of a BEOL. Together, the metal layers 130 may be referred to as a “metallization stack” of the IC structure 100. As used herein, the term “metal layer” may refer to a layer above a support structure 110 that includes electrically conductive interconnect structures (e.g., conductive lines and conductive vias) for providing electrical connectivity between different IC components. Metal layers described herein may also be referred to as “interconnect layers” to clearly indicate that these layers include electrically conductive interconnect structures which may, but does not have to, be metal. The metal layers 130 may be used to interconnect the various inputs and outputs of the active devices (e.g., transistors) in the device layer 120. Generally speaking, each of the metal layers 130 may include a conductive line (also sometimes referred to as a “trench,” a “trace,” or a “metal line”) and/or a conductive via. Conductive lines of a metal layer are configured for transferring signals and power along electrically conductive (e.g., metal) structures extending in the x-y plane (e.g., in the x or y directions), while the conductive vias of a metal layer are configured for transferring signals and power through electrically conductive structures extending in the z-direction, e.g., to any of the adjacent metal layers above or below. Accordingly, conductive vias connect interconnect structures (e.g., conductive lines and/or conductive vias) of one metal layer to interconnect structures of an adjacent metal layer. While referred to as “metal” layers, various layers of the metal layers 130 may include only certain patterns of conductive metals, e.g., copper (Cu), aluminum (Al), tungsten (W), or cobalt (Co), or metal alloys, or more generally, patterns of an electrically conductive material, formed in an insulating medium such as an interlayer dielectric (ILD). The insulating medium may include any suitable ILD materials such as silicon oxide, carbon-doped silicon oxide, silicon carbide, silicon nitride, aluminum oxide, and/or silicon oxynitride.

The bonding pads layer 140 may be a layer with conductive contacts such as bonding pads or analogous features (e.g., posts) to bond the IC structure 100 to, and to route electrical signals between the IC structure 100 and another component (not shown), such as a circuit board, a package substrate, an interposer, or another die/chip. The metal layers 130 may be between the device layer 120 and the bonding pads layer 140. As described in greater detail below, one or more vias may extend from any one of the metal layers 130 and/or from the device layer 120 to connect to one or more bonding pads in the bonding pads layer 140.

FIG. 1B illustrates a cross-sectional view of an example IC structure 100 that is similar to that shown in FIG. 1A except that it may further include a bonding layer 125 and/or a bonding layer 135. If included in the IC structure 100, the bonding layer 125 may be used to bond, electrically and mechanically, the device layer 120 to the metal layers 130, and the bonding layer 135 may be used to bond, electrically and mechanically, the metal layers 130 to the bonding pads layer 140. Implementing the bonding layers 125 and/or 135 allows applying a hybrid manufacturing approach to fabricating an IC structure 100. As used herein, the term “hybrid manufacturing” refers to fabricating a microelectronic assembly (e.g., an IC structure 100) by bonding together two or more different dies (or, more specifically, two or more IC structures that have been fabricated on different dies), thus enhancing functionality and/or performance compared to a single die, while reducing or eliminating the need to route signals between these dies through a package substrate or a circuit board. Advantageously, hybrid manufacturing approach may be used to combine/bond dies that may be fabricated by different manufacturers, using different materials, or different manufacturing techniques. For example, implementing the bonding layer 125 allows providing an IC structure 100 where the metal layers 130 are fabricated separately from the device layer 120 (e.g., fabricated by different manufacturers, using different materials, or different manufacturing techniques) and subsequently bonded to the device layer 120 by the bonding layer 125. This is contrary to conventional approaches where the metal layers 130 are fabricated directly on top of the device layer 120. Similarly, implementing the bonding layer 135 allows providing an IC structure 100 where the bonding pads layer 140 is fabricated separately from the metal layers 130 (e.g., fabricated by different manufacturers, using different materials, or different manufacturing techniques) and subsequently bonded to the metal layers 130 by the bonding layer 135. This is contrary to conventional approaches where the bonding pads layer 140 is fabricated directly on top of the metal layers 130.

In some embodiments, any of the bonding layers 125, 135 may be a direct bonding layer. As used herein, the term “direct bonding” is used to include metal-to-metal bonding techniques (e.g., copper-to-copper bonding, or other techniques in which direct bonding contacts (DB contacts) of opposing direct bonding interfaces (DB interfaces) are brought into contact first, then subject to heat and compression) and hybrid bonding techniques (e.g., techniques in which direct bonding dielectric (DB dielectric) of opposing DB interfaces, possibly first subjected to prior surface activation, are brought into contact first, then subject to heat and sometimes compression, or techniques in which the DB contacts and the DB dielectric, possibly first subjected to prior surface activation, of opposing DB interfaces are brought into contact substantially simultaneously, and the subject to heat and sometimes compression). The materials of opposing DB dielectrics can be homogeneous (i.e., have substantially the same material composition) or non-homogeneous (i.e., have different material compositions). In such techniques, the DB contacts, and the DB dielectric at one DB interface (e.g., at a DB interface of a first microelectronic component) are brought into contact with the DB contacts and the DB dielectric at another DB interface (e.g., at a DB interface of a second microelectronic component), respectively, and elevated pressures and/or temperatures may be applied to cause the contacting DB contacts and/or the contacting DB dielectrics to bond. Direct bonding may provide significant advantages over conventional coupling techniques such as solder-based interconnects or wirebonds. Direct bonding interconnects may be capable of reliably conducting a higher current than other types of interconnects; for example, some conventional solder interconnects may form large volumes of brittle intermetallic compounds when current flows, and the maximum current provided through such interconnects may be constrained to mitigate mechanical failure.

FIGS. 2A-2H illustrate cross-sectional side views of example IC structures 200 with vias connected to bonding pads, according to some embodiments of the present disclosure.

FIG. 2A illustrates an IC structure 200A, which provides one example implementation of the IC structure 100 of FIG. 1A. As shown in FIG. 2A, the IC structure 200A include a support structure 110 and a device layer 120 provided over the support structure 110, where the device layer 120 may include features of one or more transistors 222 (e.g., metal-oxide-semiconductor field-effect transistors (MOSFETs)) formed on the support structure 110. The device layer 120 may include, for example, one or more source and/or drain (S/D) regions 224, a gate 226 to control current flow in the transistors 222 between the S/D regions 224, and one or more S/D contacts 228 to route electrical signals to/from the S/D regions 224. The transistors 222 may include additional features not depicted for the sake of clarity, such as device isolation regions, gate contacts, and the like. The transistors 222 are not limited to the type and configuration depicted in FIG. 2A and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

The S/D regions 224 may be formed within the support structure 110 adjacent to the gate 226 of each transistor 222, using any suitable processes known in the art. For example, the S/D regions 224 may be formed using either an implantation/diffusion process or a deposition process. In the former process, dopants such as boron, aluminum, antimony, phosphorous, or arsenic may be ion-implanted into the support structure 110 to form the S/D regions 224. An annealing process that activates the dopants and causes them to diffuse farther into the support structure 110 may follow the ion implantation process. In the latter process, an epitaxial deposition process may provide material that is used to fabricate the S/D regions 224. In some implementations, the S/D regions 224 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 224 may be formed using one or more alternate semiconductor materials such as germanium or a group III-V material or alloy. In further embodiments, one or more layers of metal and/or metal alloys may be used to form the S/D regions 224. In some embodiments, an etch process may be performed before the epitaxial deposition to create recesses in the support structure 110 in which the material for the S/D regions 224 is deposited.

Each transistor 222 may include a gate 226 formed of at least two layers, a gate electrode layer and a gate dielectric layer. The gate electrode layer may be formed on the gate interconnect support layer and may consist of at least one P-type workfunction metal or N-type workfunction metal, depending on whether the transistor is to be a P-type metal-oxide-semiconductor (PMOS) or an N-type metal-oxide-semiconductor (NMOS) transistor, respectively. In some implementations, the gate electrode layer may consist of a stack of two or more metal layers, where one or more metal layers are workfunction metal layers and at least one metal layer is a fill metal layer. Further metal layers may be included for other purposes, such as a barrier layer or/and an adhesion layer. For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 2.9 electron Volts (eV) and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, aluminum carbide, tungsten, tungsten carbide. An N-type metal layer will enable the formation of an NMOS gate electrode with a workfunction that is between about 3.9 eV and about 2.2 eV.

In some embodiments, when viewed as a cross-section of the transistor 222 along the source-channel-drain direction, the gate electrode may be formed as a U-shaped structure that includes a bottom portion substantially parallel to the surface of the substrate and two sidewall portions that are substantially perpendicular to the top surface of the substrate. In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may be implemented as a combination of U-shaped structures and planar, non-U-shaped structures. For example, the gate electrode may be implemented as one or more U-shaped metal layers formed atop one or more planar, non-U-shaped layers. In some embodiments, the gate electrode may consist of a V-shaped structure (e.g., when a fin of a FinFET transistor does not have a “flat” upper surface, but instead has a rounded peak).

Generally, the gate dielectric layer of a transistor 222 may include one layer or a stack of layers, and the one or more layers may include silicon oxide, silicon dioxide, and/or a high-k dielectric material. The high-k dielectric material included in the gate dielectric layer of the transistor 222 may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

Electrical signals, such as power and/or input/output (I/O) signals, may be routed to and/or from the transistors 222 of the device layer 120 through one or more metal layers 130 disposed on the device layer 120, illustrated in FIG. 2A as metal layers 130-1, 130-2, and 130-3. For example, electrically conductive features of the device layer 120 (e.g., the gate 226 and the S/D contacts 228) may be electrically coupled with the interconnect structures 232 of the metal layers 130. Although a particular number of metal layers 130 is depicted in FIG. 2A, embodiments of the present disclosure include IC devices having more or fewer metal layers than depicted. The one or more metal layers 130 may form a metallization stack of the IC structure 200A.

The interconnect structures 232 may be arranged within the metal layers 130 of the IC device 200A to route electrical signals according to a wide variety of designs (in particular, the arrangement is not limited to the particular configuration of interconnect structures 232 depicted in FIG. 2A). In some embodiments, the interconnect structures 232 may include conductive lines 232a and/or conductive vias 232b, formed of an electrically conductive material such as a metal. The conductive lines 232a may be arranged to route electrical signals in a direction of a plane that is substantially parallel with a surface of the support structure 110 upon which the device layer 120 is formed. For example, the conductive lines 232a may route electrical signals in a direction in and out of the page from the perspective of FIG. 2A. The conductive vias 232b may be arranged to route electrical signals in a direction of a plane that is substantially perpendicular to the surface of the support structure 110 upon which the device layer 120 is formed. In some embodiments, the conductive vias 232b may electrically couple conductive lines 232a of different metal layers 130 together.

A first metal layer 130-1 (referred to as Metal 1 or “M1”) may be provided directly over the device layer 120. In some embodiments, the first metal layer 130-1 may include conductive lines 232a and/or conductive vias 232b, as shown. The conductive lines 232a of the first metal layer 130-1 may be coupled with contacts (e.g., the S/D contacts 228) of the device layer 120.

A second metal layer 130-2 (referred to as Metal 2 or “M2”) may be formed directly on the first metal layer 130-1. In some embodiments, the second metal layer 130-2 may include conductive vias 232b to couple the conductive lines 232a of the second metal layer 130-2 with the conductive lines 232a of the first metal layer 130-1. Although the conductive lines 232a and the conductive vias 232b are structurally delineated with a line within each metal layer (e.g., within the second metal layer 130-2) for the sake of clarity, the conductive lines 232a and the conductive vias 232b may be structurally and/or materially contiguous (e.g., simultaneously filled during a dual-damascene process) in some embodiments.

A third metal layer 130-3 (referred to as Metal 3 or “M3”) (and additional metal layers, as desired) may be formed in succession on the second metal layer 130-2 according to similar techniques and configurations described in connection with the second metal layer 130-2 or the first metal layer 130-1.

The metal layers 130 may include a dielectric material 234 disposed between the interconnect structures 232, as shown in FIG. 2A. In some embodiments, the dielectric material 234 disposed between the interconnect structures 232 in different ones of the metal layers 130 may have different compositions. In other embodiments, the composition of the dielectric material 234 in different metal layers 130 may be the same. The dielectric material 234 may be one or more layers of any suitable insulator materials, such as any ILD materials described above. In some embodiments, the dielectric material 234 may be a low-k dielectric material. Examples of the low-k dielectric materials that may be used as the dielectric material 234 include, but are not limited to, silicon dioxide, carbon-doped oxide, silicon nitride, fused silica glass (FSG), and organosilicates such as silsesquioxane, siloxane, and organosilicate glass. Other examples of low-k dielectric materials that may be used as the dielectric material 234 include organic polymers such as polyimide, polynorbornenes, benzocyclobutene, perfluorocyclobutane, or polytetrafluoroethylene (PTFE). Still other examples of low-k dielectric materials that may be used as the dielectric material 234 include silicon-based polymeric dielectrics such as hydrogen silsesquioxane (HSQ) and methylsilsesquioxane (MSQ). In some embodiments, the dielectric material 234 may include any suitable semiconductor material together with oxygen (e.g., the dielectric material 234 may be an oxide of a semiconductor material) or together with nitrogen (e.g., the dielectric material 234 may be a nitride of a semiconductor material), or together with oxygen and nitrogen (e.g., the dielectric material 234 may be an oxynitride of a semiconductor material).

The bonding pads layer 140 of the IC structure 200A may include bonding pads 242 or analogous conductive contacts (e.g., posts) and an insulator material 244, e.g., a solder resist material (e.g., polyimide or similar material) around the bonding pads 242. The bonding pads 242 may be electrically coupled with the interconnect structures 232 and configured to route the electrical signals of the transistor(s) 222 or of other semiconductor device components of the device layer 120 and/or of the metal layers 130 to other external devices. For example, solder bonds may be formed on the one or more bonding pads 242 to mechanically and/or electrically couple a chip including the IC structure 200A with another component (e.g., a circuit board). The IC structure 200A may have other alternative configurations to route the electrical signals from the metal layers 130 than depicted in other embodiments. The bonding pads 242 may include any of the electrically conductive materials described herein or known in the art, e.g., any of the metals or metal alloys.

As shown in FIG. 2A, besides conventional conductive vias 232b provided in individual metal layers 130, the IC structure 200A may further include at least one of a conductive via 252, a conductive via 254, and/or a conductive via stack 256 of a plurality of conductive vias 232b. Each of the conductive vias 252, 254, and the conductive via stack 256 may connect one or more electrical components of the device layer 120 and/or the metal layers 130 (e.g., one or more terminals of semiconductor device components in the device layer 120 or the metal layers 130, or any of the interconnect structures 232 of the device layer 120 or the metal layers 130) to one or more bonding pads 242.

As shown in FIG. 2A, conductive via 252 may connect one of the interconnect structures 232 in the device layer 120 (e.g., a conductive line 232a in the device layer 120 or one of the terminals of a transistor 222 in the device layer 120) to one of the bonding pads 242. To that end, conductive via 252 may extend through all of the metal layers 130 to reach the one of the bonding pads 242. In other embodiments, conductive via 252 may connect one of the interconnect structures 232 in one of the metal layers 130 or one of the terminals of a semiconductor device component such as the transistor 222 in the metal layers 130 to one of the bonding pads 242. To that end, conductive via 252 may extend through all of the subsequent metal layers 130 to reach the one of the bonding pads 242.

As further shown in FIG. 2A, conductive via 254 may extend through two or more layers of the metal layers 130 to connect one of the interconnect structures 232 in the device layer 120 (e.g., a conductive line 232a in the device layer 120 or one of the terminals of a transistor 222 in the device layer 120) to another conductive via 232b in one of the metal layers 130, which may then connect to one of the bonding pads 242. In other embodiments, conductive via 254 may connect to a plurality of conductive vias 232b in subsequent metal layers 130, the last one of which may then connect to one of the bonding pads 242 (e.g., similar to the conductive via stack 256).

As also shown in FIG. 2A, conductive via stack 256 may include a plurality of conductive vias 232b in subsequent metal layers 130. The first conductive via 232b of the conductive via stack 256 may connect to one of the interconnect structures 232 or transistors 222 in the device layer 120, or to one of the interconnect structures 232 or transistors 222 in one of the metal layers 130. The last conductive via 232b of the conductive via stack 256 may then connect to one of the bonding pads 242.

For certain manufacturing processes, cross-sectional shapes of interconnect structures, in particular, conductive vias 232b and bonding pads 242, in the plane such as that shown in FIG. 1A may be substantially trapezoidal, i.e., a cross-section of a conductive via 232b or a bonding pad 242 may have two substantially parallel ends, one of which may be referred to as a “short end” and another one of which may be referred to as a “long end,” with the long end being closer to the top face of an IC structure on which the conductive via 232b or the bonding pad 242 is fabricated than the short end (i.e., the long end may face the front of the IC structure, while the short side may face the back of the IC structure). For example, dual-Damascene or single-Damascene processes for manufacturing interconnects could result in such trapezoidal cross-sections. Examining the trapezoidal cross-sectional shapes of the bonding pads 242 and of the conductive vias 232b, 252, and 254 may, therefore, be indicative of how they were fabricated. For example, the IC structure 200A is an example of the IC structure 100 of FIG. 1A, where the metal layers 130 were directly fabricated on top of the device layer 120, and the bonding pads layer 140 was directly fabricated on top of the metal layers 130. Consequently, all of the trapezoidal shapes of the bonding pads 242, and conductive vias 232b, 252, and 254 are facing the same way. Namely, in the IC structure 200A, the short ends of the bonding pads 242 and conductive vias 232b, 252, and 254 are closer to the device layer 120 than their long ends.

FIGS. 2B-2G illustrates IC structures 200B, which are similar to the IC structure 200A but further include a bonding layer 125 and/or a bonding layer 135, thus providing different example implementations of the IC structure 100 of FIG. 1B.

As shown in FIG. 2B, the IC structure 200B may include a bonding layer 125 between the device layer 120 and the lowest one of the metal layers 130. As shown in FIG. 2B, the bonding layer 125 may include bonding contacts 262 and a bonding dielectric 264 around the bonding contacts 262. The bonding layer 125 may bond (e.g., electrically and mechanically) one or more of the interconnect structures 232 or transistors 222 in the device layer 120 and one or more of the interconnect structures 232 or transistors 222 in the lowest one of the metal layers 130. For example, an individual bonding contact 262 may substantially align with one of the interconnect structures 232 or terminals of a transistor 222 in the device layer 120 and one of the interconnect structures 232 or terminals of a transistor 222 in the lowest one of the metal layers 130. In some embodiments, the bonding contacts 262 may be DB contacts as described above, and the bonding dielectric 264 may be a DB dielectric as described above. The bonding contacts 262 may include any of the electrically conductive materials described herein or known in the art, e.g., any of the metals or metal alloys. The bonding dielectric 264 may include any of the insulator materials described herein or known in the art.

Because the bonding layer 125 is included between the device layer 120 and the metal layers 130, the IC structure 200B is an example of an IC structure where the device layer 120 and the metal layers 130 were fabricated separately (e.g., fabricated by different manufacturers, using different materials, or different manufacturing techniques) and subsequently bonded together by the bonding layer 125. As a result, some embodiments may include bonding the metal layers 130 face down to the device region 120. This is shown in FIG. 2B, illustrating that the trapezoidal shapes of the conductive vias 232b, 252, and 254 are facing the opposite way compared to FIG. 2A. Namely, in the IC structure 200B, the long ends of the conductive vias 232b, 252, and 254 are closer to the device layer 120 than their short ends. Because the IC structure 200B does not include a bonding layer 135 between the metal layers 130 and the bonding pads layer 140, it means that the bonding pads layer 140 was directly fabricated on top of the metal layers 130 after the metal layers 130 were bonded to the device layer 120. Consequently, all of the trapezoidal shapes of the bonding pads 242 in FIG. 2B are facing the same way as in FIG. 2A. Namely, in the IC structure 200B, the short ends of the bonding pads 242 are closer to the device layer 120 than their long ends.

In some embodiments, the IC structure 200 may include etch-stop materials within the device layer 120 and within a stack of metal layers 130 (e.g., between adjacent metal layers 130). Such layers of etch-stop materials are commonly used in the field of semiconductor manufacturing, and may be provided at different locations of the IC structures 100/200, the locations being dependent on, e.g., specific processing techniques used to manufacture portions of these IC structures. Any location of the etch-stop materials within the IC structures 100/200 as known in the art are possible and are within the scope of the present disclosure. What is unique about the etch-stop materials in context of hybrid manufacturing is that because the device layer 120 and the metal layers 130 may be fabricated by different manufacturers, using different materials, or different manufacturing techniques and then bonded together using the bonding layer 125, the material compositions of their etch-stop materials may be different. For example, the etch-stop material within the device layer 120 may include a material with silicon and nitrogen (e.g., silicon nitride), while the etch-stop material within the stack of metal layers 130 may include a material with silicon and carbon (e.g., silicon carbide), or vice versa, or one of these etch-stop materials may include a material with aluminum and oxygen (e.g., aluminum oxide). Furthermore, the bonding layer 125 at the interface between the device layer 120 and the stack of metal layers 130 may have a material composition different from one or both of the etch-stop material within the device layer 120 and the etch-stop material within the stack of metal layers 130. For example, in some embodiments, the bonding layer 125 may include silicon, nitrogen, and carbon, where the atomic percentage of any of these materials may be at least 1%, e.g., between about 1% and 50%, indicating that these elements are added deliberately, as opposed to being accidental impurities which are typically in concentration below about 0.1%. Having both nitrogen and carbon in these concentrations in addition to silicon is not typically used in conventional semiconductor manufacturing processes where, typically, either nitrogen or carbon is used in combination with silicon, and, therefore, would be a characteristic feature of the hybrid manufacturing as described herein. Using an etch-stop material at the interface between the device layer 120 and the stack of metal layers 130 that includes include silicon, nitrogen, and carbon, where the atomic percentage of any of these materials may be at least 1%, e.g., SiOCN, may be advantageous in terms that such a material may act both as an etch-stop material, and have sufficient adhesive properties to bond the device layer 120 and the stack of metal layers 130 together. In addition, an etch-stop material at the interface between the device layer 120 and the stack of metal layers 130 that includes include silicon, nitrogen, and carbon, where the atomic percentage of any of these materials may be at least 1%, may be advantageous in terms of improving etch-selectivity of this material with respect to the etch-stop materials of the device layer 120 and/or of the stack of metal layers 130.

Other embodiments where the bonding layer 125 is included between the device layer 120 and the metal layers 130, may include bonding the metal layers 130 face up to the device region 120. This is shown in FIG. 2C, illustrating an IC structure 200C that is substantially the same as the IC structure 200B shown in FIG. 2B, but illustrating that the trapezoidal shapes of the conductive vias 232b, 252, and 254 are facing the opposite way compared to FIG. 2B. Namely, in the IC structure 200C, the short ends of the conductive vias 232b, 252, and 254 are closer to the device layer 120 than their long ends. Similar to the IC structure 200B, because the IC structure 200C does not include a bonding layer 135 between the metal layers 130 and the bonding pads layer 140, it means that the bonding pads layer 140 was directly fabricated on top of the metal layers 130 after the metal layers 130 were bonded to the device layer 120. Consequently, all of the trapezoidal shapes of the bonding pads 242 in FIG. 2C are facing the same way as in FIG. 2A. Namely, in the IC structure 200C, the short ends of the bonding pads 242 are closer to the device layer 120 than their long ends. Thus, the IC structure 200C shown in FIG. 2C is substantially the same as the IC structure 200A shown in FIG. 2A, but further including the bonding layer 125.

As shown in FIG. 2D, an IC structure 200D may include a bonding layer 125 as described above, and further include a bonding layer 135 between the top one of the metal layers 130 and the bonding pads layer 140. As shown in FIG. 2D, the bonding layer 135 may include bonding contacts 262 and a bonding dielectric 264 around the bonding contacts 262, similar to those described with reference to the bonding layer 125. The bonding layer 145 may bond (e.g., electrically and mechanically) one or more of the interconnect structures 232 or transistors 222 in the top one of the metal layers 130 and one or more of the bonding pads 242. For example, an individual bonding contact 262 in the bonding layer 135 may substantially align with one of the interconnect structures 232 or terminals of a transistor 222 in the top one of the metal layers 130 and one of the bonding pads 242.

Because the bonding layer 135 is included between the metal layers 130 and the bonding pads layer 140, the IC structure 200D is an example of an IC structure where the metal layers 130 and the bonding pads layer 140 were fabricated separately (e.g., fabricated by different manufacturers, using different materials, or different manufacturing techniques) and subsequently bonded together by the bonding layer 135. As a result, some embodiments may include bonding the bonding pads layer 140 face down to the metal layers 130. This is shown in FIG. 2D, illustrating that the trapezoidal shapes of the bonding pads 242 are facing the opposite way compared to FIG. 2B and compared to FIG. 2A. Namely, in the IC structure 200D, the long ends of the bonding pads 242 are closer to the device layer 120 than their short ends. The IC structure 200D is further an example where the metal layers 130 were bonded face down to the device layer 120 using the bonding layer 125, as in FIG. 2B. Therefore, similar to FIG. 2B, FIG. 2D illustrates that the trapezoidal shapes of the conductive vias 232b, 252, and 254 are facing the opposite way compared to FIG. 2A. Namely, in the IC structure 200D, the long ends of the conductive vias 232b, 252, and 254 are closer to the device layer 120 than their short ends.

Other embodiments where the bonding layer 135 is included between the metal layers 130 and the bonding pads layer 140, may include bonding the bonding pads layer 140 face up to the metal layers 130. This is shown in FIG. 2E, illustrating an IC structure 200E that is substantially the same as the IC structure 200D shown in FIG. 2D, but illustrating that the trapezoidal shapes of the bonding pads 242 are facing the opposite way compared to FIG. 2D. Namely, in the IC structure 200E, the short ends of the bonding pads 242 are closer to the device layer 120 than their long ends. Thus, the IC structure 200E shown in FIG. 2E is substantially the same as the IC structure 200B shown in FIG. 2B, but further including the bonding layer 135.

FIG. 2F illustrates an IC structure 200F that includes the metal layers 130 bonded face up to the device layer 120 using the bonding layer 125, as in FIG. 2C, and further including the bonding pads layer 140 bonded face down to the metal layers 130 using the bonding layer 135, as in FIG. 2D. Consequently, the trapezoidal shapes of the conductive vias 232b, 252, and 254 are arranged as described for FIG. 2C, and the trapezoidal shapes of the bonding pads 242 are arranged as described for FIG. 2D.

FIG. 2G illustrates an IC structure 200G that includes the metal layers 130 bonded face up to the device layer 120 using the bonding layer 125, as in FIG. 2C, and further including the bonding pads layer 140 bonded face up to the metal layers 130 using the bonding layer 135, as in FIG. 2E. Consequently, the trapezoidal shapes of the conductive vias 232b, 252, and 254 are arranged as described for FIG. 2C, and the trapezoidal shapes of the bonding pads 242 are arranged as described for FIG. 2E.

FIG. 2H illustrates an IC structure 200H that is substantially the same as the IC structure 200A of FIG. 2A, but the conductive via 252 connects one of the electrical components of the metal layers 130 (e.g., one of the interconnect structures 232 of the metal layers 130) to one or more bonding pads 242. Similar to FIG. 2A, the IC structure 200H is another example of the IC structure 100 of FIG. 1A. The trapezoidal shapes of the conductive vias 232b, 252, and 254 are arranged in FIG. 2H as described for FIG. 2A.

Together, the IC structures 200A-200H may be referred to as “IC structures 200.”

Various arrangements of the IC structures as illustrated in FIGS. 1-2 do not represent an exhaustive set of IC structures that may implement one or more vias connected to bonding pads as described herein, but merely provide examples of such devices/structures/assemblies. In particular, the number and positions of various elements shown in FIGS. 1-2 is purely illustrative and, in various other embodiments, other numbers of these elements, provided in other locations relative to one another may be used in accordance with the general architecture considerations described herein.

Arrangements with an IC structure with one or more vias connected to bonding pads as disclosed herein may be included in any suitable electronic device. FIGS. 3-7 illustrate various examples of devices and components that may include an IC structure with one or more vias connected to bonding pads as disclosed herein.

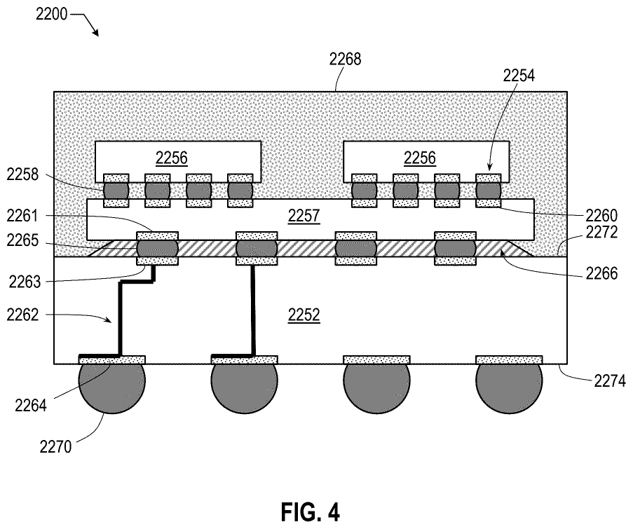

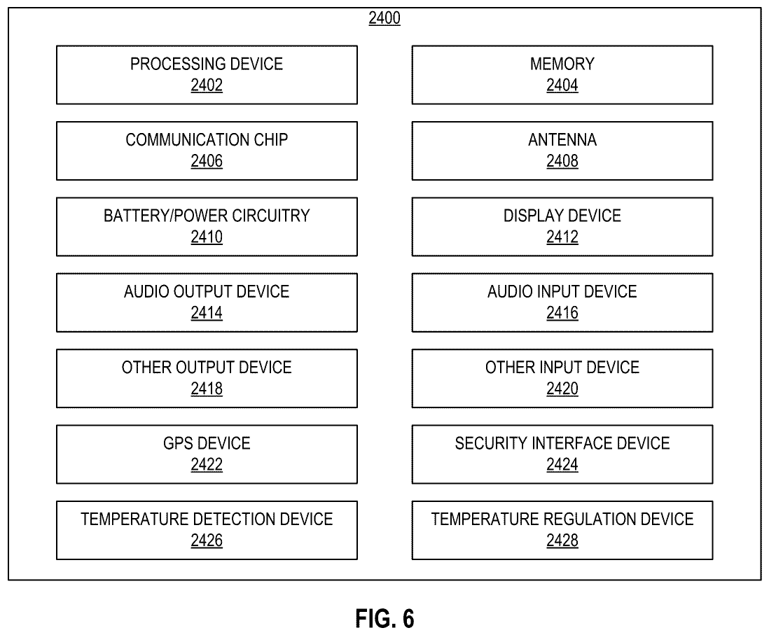

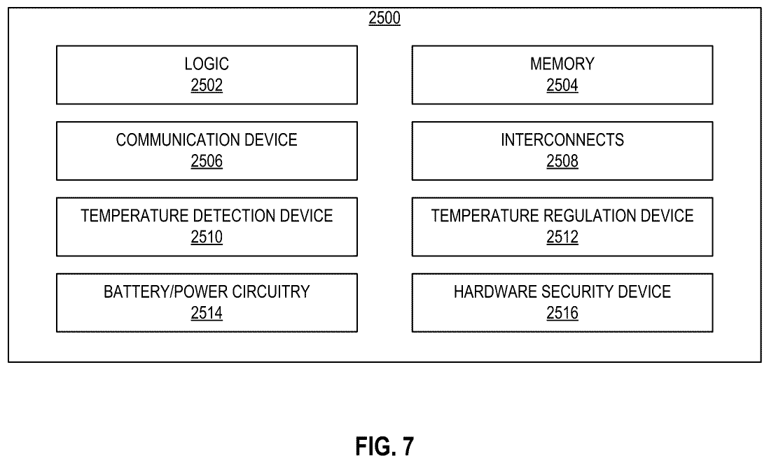

FIG. 3 illustrates top views of a wafer 2000 and dies 2002 that may include an IC structure with one or more vias connected to bonding pads in accordance with any of the embodiments disclosed herein. In some embodiments, the dies 2002 may be included in an IC package, in accordance with any of the embodiments disclosed herein. For example, any of the dies 2002 may serve as any of the dies 2256 in an IC package 2200 shown in FIG. 4. The wafer 2000 may be composed of semiconductor material and may include one or more dies 2002 having IC structures formed on a surface of the wafer 2000. Each of the dies 2002 may be a repeating unit of a semiconductor product that includes any suitable IC (e.g., ICs including one or more vias connected to bonding pads as described herein). After the fabrication of the semiconductor product is complete (e.g., after manufacture of any embodiment of the IC structure 100 as described herein), the wafer 2000 may undergo a singulation process in which each of the dies 2002 is separated from one another to provide discrete “chips” of the semiconductor product. In particular, devices that include IC structures with one or more vias connected to bonding pads as disclosed herein may take the form of the wafer 2000 (e.g., not singulated) or the form of the die 2002 (e.g., singulated). The die 2002 may include supporting circuitry to route electrical signals to various memory cells, transistors, capacitors, as well as any other IC components. In some embodiments, the wafer 2000 or the die 2002 may implement or include a memory device, a logic device (e.g., an AND, OR, NAND, or NOR gate), or any other suitable circuit element. Multiple ones of these devices may be combined on a single die 2002. For example, a memory array formed by multiple memory devices may be formed on a same die 2002 as a processing device (e.g., the processing device 2402 of FIG. 6 or the logic 2502 of FIG. 7) or other logic that is configured to store information in the memory devices or execute instructions stored in the memory array.

FIG. 4 is a side, cross-sectional view of an example IC package 2200 that may include an IC structure with one or more vias connected to bonding pads in accordance with any of the embodiments disclosed herein. In some embodiments, the IC package 2200 may be a system-in-package (SiP).

The package substrate 2252 may be formed of a dielectric material (e.g., a ceramic, a buildup film, an epoxy film having filler particles therein, etc.), and may have conductive pathways extending through the dielectric material between the face 2272 and the face 2274, or between different locations on the face 2272, and/or between different locations on the face 2274.

The package substrate 2252 may include conductive contacts 2263 that are coupled to conductive pathways 2262 through the package substrate 2252, allowing circuitry within the dies 2256 and/or the interposer 2257 to electrically couple to various ones of the conductive contacts 2264 (or to other devices included in the package substrate 2252, not shown).

The IC package 2200 may include an interposer 2257 coupled to the package substrate 2252 via conductive contacts 2261 of the interposer 2257, first-level interconnects 2265, and the conductive contacts 2263 of the package substrate 2252. The first-level interconnects 2265 illustrated in FIG. 4 are solder bumps, but any suitable first-level interconnects 2265 may be used. In some embodiments, no interposer 2257 may be included in the IC package 2200; instead, the dies 2256 may be coupled directly to the conductive contacts 2263 at the face 2272 by first-level interconnects 2265.

The IC package 2200 may include one or more dies 2256 coupled to the interposer 2257 via conductive contacts 2254 of the dies 2256, first-level interconnects 2258, and conductive contacts 2260 of the interposer 2257. The conductive contacts 2260 may be coupled to conductive pathways (not shown) through the interposer 2257, allowing circuitry within the dies 2256 to electrically couple to various ones of the conductive contacts 2261 (or to other devices included in the interposer 2257, not shown). The first-level interconnects 2258 illustrated in FIG. 4 are solder bumps, but any suitable first-level interconnects 2258 may be used. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

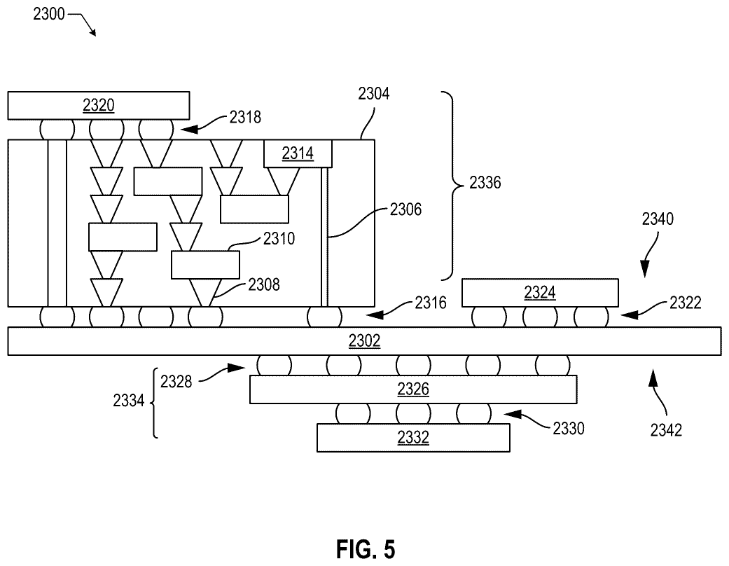

In some embodiments, an underfill material 2266 may be disposed between the package substrate 2252 and the interposer 2257 around the first-level interconnects 2265, and a mold compound 2268 may be disposed around the dies 2256 and the interposer 2257 and in contact with the package substrate 2252. In some embodiments, the underfill material 2266 may be the same as the mold compound 2268. Example materials that may be used for the underfill material 2266 and the mold compound 2268 are epoxy mold materials, as suitable. Second-level interconnects 2270 may be coupled to the conductive contacts 2264. The second-level interconnects 2270 illustrated in FIG. 4 are solder balls (e.g., for a ball grid array arrangement), but any suitable second-level interconnects 22770 may be used (e.g., pins in a pin grid array arrangement or lands in a land grid array arrangement). The second-level interconnects 2270 may be used to couple the IC package 2200 to another component, such as a circuit board (e.g., a motherboard), an interposer, or another IC package, as known in the art and as discussed below with reference to FIG. 5.

The dies 2256 may take the form of any of the embodiments of the die 2002 discussed herein (e.g., may include any of the embodiments of the IC structures with one or more vias connected to bonding pads as described herein). In embodiments in which the IC package 2200 includes multiple dies 2256, the IC package 2200 may be referred to as a multi-chip package (MCP). The dies 2256 may include circuitry to perform any desired functionality. For example, one or more of the dies 2256 may be logic dies (e.g., silicon-based dies), and one or more of the dies 2256 may be memory dies (e.g., high-bandwidth memory), including embedded memory dies as described herein. In some embodiments, any of the dies 2256 may include an IC structure with one or more vias connected to bonding pads, e.g., as discussed above; in some embodiments, at least some of the dies 2256 may not include any IC structures with one or more vias connected to bonding pads.

The IC package 2200 illustrated in FIG. 4 may be a flip chip package, although other package architectures may be used. For example, the IC package 2200 may be a ball grid array (BGA) package, such as an embedded wafer-level ball grid array (eWLB) package. In another example, the IC package 2200 may be a wafer-level chip scale package (WLCSP) or a panel fan-out (FO) package. Although two dies 2256 are illustrated in the IC package 2200 of FIG. 4, an IC package 2200 may include any desired number of the dies 2256. An IC package 2200 may include additional passive components, such as surface-mount resistors, capacitors, and inductors disposed on the first face 2272 or the second face 2274 of the package substrate 2252, or on either face of the interposer 2257. More generally, an IC package 2200 may include any other active or passive components known in the art.

FIG. 5 is a cross-sectional side view of an IC device assembly 2300 that may include components having an IC structure with one or more vias connected to bonding pads in accordance with any of the embodiments disclosed herein. The IC device assembly 2300 includes a number of components disposed on a circuit board 2302 (which may be, e.g., a motherboard). The IC device assembly 2300 includes components disposed on a first face 2340 of the circuit board 2302 and an opposing second face 2342 of the circuit board 2302; generally, components may be disposed on one or both faces 2340 and 2342. In particular, any suitable ones of the components of the IC device assembly 2300 may include any of IC structures with one or more vias connected to bonding pads in accordance with any of the embodiments disclosed herein; e.g., any of the IC packages discussed below with reference to the IC device assembly 2300 may take the form of any of the embodiments of the IC package 2200 discussed above with reference to FIG. 4 (e.g., may include an IC structure with one or more vias connected to bonding pads provided on a die 2256).

In some embodiments, the circuit board 2302 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2302. In other embodiments, the circuit board 2302 may be a non-PCB substrate.

The IC device assembly 2300 illustrated in FIG. 5 includes a package-on-interposer structure 2336 coupled to the first face 2340 of the circuit board 2302 by coupling components 2316. The coupling components 2316 may electrically and mechanically couple the package-on-interposer structure 2336 to the circuit board 2302, and may include solder balls (e.g., as shown in FIG. 5), male and female portions of a socket, an adhesive, an underfill material, and/or any other suitable electrical and/or mechanical coupling structure.

The package-on-interposer structure 2336 may include an IC package 2320 coupled to an interposer 2304 by coupling components 2318. The coupling components 2318 may take any suitable form for the application, such as the forms discussed above with reference to the coupling components 2316. The IC package 2320 may be or include, for example, a die (the die 2002 of FIG. 3), an IC device, or any other suitable component. In particular, the IC package 2320 may include an IC structure with one or more vias connected to bonding pads as described herein. Although a single IC package 2320 is shown in FIG. 5, multiple IC packages may be coupled to the interposer 2304; indeed, additional interposers may be coupled to the interposer 2304. The interposer 2304 may provide an intervening substrate used to bridge the circuit board 2302 and the IC package 2320. Generally, the interposer 2304 may spread a connection to a wider pitch or reroute a connection to a different connection. For example, the interposer 2304 may couple the IC package 2320 (e.g., a die) to a BGA of the coupling components 2316 for coupling to the circuit board 2302. In the embodiment illustrated in FIG. 5, the IC package 2320 and the circuit board 2302 are attached to opposing sides of the interposer 2304; in other embodiments, the IC package 2320 and the circuit board 2302 may be attached to a same side of the interposer 2304. In some embodiments, three or more components may be interconnected by way of the interposer 2304.

The interposer 2304 may be formed of an epoxy resin, a fiberglass-reinforced epoxy resin, a ceramic material, or a polymer material such as polyimide. In some implementations, the interposer 2304 may be formed of alternate rigid or flexible materials that may include the same materials described above for use in a semiconductor substrate, such as silicon, germanium, and other group III-V and group IV materials. The interposer 2304 may include metal interconnects 2308 and vias 2310, including but not limited to through-silicon vias (TSVs) 2306. The interposer 2304 may further include embedded devices 2314, including both passive and active devices. Such devices may include, but are not limited to, capacitors, decoupling capacitors, resistors, inductors, fuses, diodes, transformers, sensors, electrostatic discharge (ESD) protection devices, and memory devices. More complex devices such as radio frequency (RF) devices, power amplifiers, power management devices, antennas, arrays, sensors, and microelectromechanical systems (MEMS) devices may also be formed on the interposer 2304. The package-on-interposer structure 2336 may take the form of any of the package-on-interposer structures known in the art.

The IC device assembly 2300 may include an IC package 2324 coupled to the first face 2340 of the circuit board 2302 by coupling components 2322. The coupling components 2322 may take the form of any of the embodiments discussed above with reference to the coupling components 2316, and the IC package 2324 may take the form of any of the embodiments discussed above with reference to the IC package 2320.

The IC device assembly 2300 illustrated in FIG. 5 includes a package-on-package structure 2334 coupled to the second face 2342 of the circuit board 2302 by coupling components 2328. The package-on-package structure 2334 may include an IC package 2326 and an IC package 2332 coupled together by coupling components 2330 such that the IC package 2326 is disposed between the circuit board 2302 and the IC package 2332. The coupling components 2328 and 2330 may take the form of any of the embodiments of the coupling components 2316 discussed above, and the IC packages 2326 and 2332 may take the form of any of the embodiments of the IC package 2320 discussed above. The package-on-package structure 2334 may be configured in accordance with any of the package-on-package structures known in the art.

FIG. 6 is a block diagram of an example computing device 2400 that may include one or more components including an IC structure with one or more vias connected to bonding pads in accordance with any of the embodiments disclosed herein. For example, any suitable ones of the components of the computing device 2400 may include a die (e.g., the die 2002 of FIG. 3) having one or more IC structures with one or more vias connected to bonding pads as described herein. Any one or more of the components of the computing device 2400 may include, or be included in, an IC package 2200 of FIG. 4 or an IC device 2300 of FIG. 5.

A number of components are illustrated in FIG. 6 as included in the computing device 2400, but any one or more of these components may be omitted or duplicated, as suitable for the application. In some embodiments, some or all of the components included in the computing device 2400 may be attached to one or more motherboards. In some embodiments, some or all of these components are fabricated onto a single system-on-chip (SoC) die.

Additionally, in various embodiments, the computing device 2400 may not include one or more of the components illustrated in FIG. 6, but the computing device 2400 may include interface circuitry for coupling to the one or more components. For example, the computing device 2400 may not include a display device 2412, but may include display device interface circuitry (e.g., a connector and driver circuitry) to which a display device 2412 may be coupled. In another set of examples, the computing device 2400 may not include an audio input device 2416 or an audio output device 2414, but may include audio input or output device interface circuitry (e.g., connectors and supporting circuitry) to which an audio input device 2416 or audio output device 2414 may be coupled.

The computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2402 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The computing device 2400 may include a memory 2404, which may itself include one or more memory devices such as volatile memory (e.g., DRAM), nonvolatile memory (e.g., read-only memory (ROM)), flash memory, solid state memory, and/or a hard drive. In some embodiments, the memory 2404 may include memory that shares a die with the processing device 2402. This memory may be used as cache memory and may include embedded DRAM (eDRAM) or spin transfer torque MRAM.

In some embodiments, the computing device 2400 may include a communication chip 2406 (e.g., one or more communication chips). For example, the communication chip 2406 may be configured for managing wireless communications for the transfer of data to and from the computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2406 may implement any of a number of wireless standards or protocols, including but not limited to Institute for Electrical and Electronic Engineers (IEEE) standards including Wi-Fi (IEEE 1402.11 family), IEEE 1402.16 standards (e.g., IEEE 1402.16-2005Amendment), Long-Term Evolution (LTE) project along with any amendments, updates, and/or revisions (e.g., advanced LTE project, ultramobile broadband (UMB) project (also referred to as “3GPP2”), etc.). IEEE 1402.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 1402.16 standards. The communication chip 2406 may operate in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or LTE network. The communication chip 2406 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2406 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2406 may operate in accordance with other wireless protocols in other embodiments. The computing device 2400 may include an antenna 2408 to facilitate wireless communications and/or to receive other wireless communications (such as AM or FM radio transmissions).

In some embodiments, the communication chip 2406 may manage wired communications, such as electrical, optical, or any other suitable communication protocols (e.g., the Ethernet). As noted above, the communication chip 2406 may include multiple communication chips. For instance, a first communication chip 2406 may be dedicated to shorter-range wireless communications such as Wi-Fi or Bluetooth, and a second communication chip 2406 may be dedicated to longer-range wireless communications such as global positioning system (GPS), EDGE, GPRS, CDMA, WiMAX, LTE, EV-DO, or others. In some embodiments, a first communication chip 2406 may be dedicated to wireless communications, and a second communication chip 2406 may be dedicated to wired communications.

The computing device 2400 may include a battery/power circuitry 2410. The battery/power circuitry 2410 may include one or more energy storage devices (e.g., batteries or capacitors) and/or circuitry for coupling components of the computing device 2400 to an energy source separate from the computing device 2400 (e.g., AC line power).

The computing device 2400 may include a display device 2412 (or corresponding interface circuitry, as discussed above). The display device 2412 may include any visual indicators, such as a heads-up display, a computer monitor, a projector, a touchscreen display, a liquid crystal display (LCD), a light-emitting diode display, or a flat panel display, for example.

The computing device 2400 may include an audio output device 2414 (or corresponding interface circuitry, as discussed above). The audio output device 2414 may include any device that generates an audible indicator, such as speakers, headsets, or earbuds, for example.

The computing device 2400 may include an audio input device 2416 (or corresponding interface circuitry, as discussed above). The audio input device 2416 may include any device that generates a signal representative of a sound, such as microphones, microphone arrays, or digital instruments (e.g., instruments having a musical instrument digital interface (MIDI) output).

The computing device 2400 may include an other output device 2418 (or corresponding interface circuitry, as discussed above). Examples of the other output device 2418 may include an audio codec, a video codec, a printer, a wired or wireless transmitter for providing information to other devices, or an additional storage device.

The computing device 2400 may include an other input device 2420 (or corresponding interface circuitry, as discussed above). Examples of the other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2400 may include a GPS device 2422 (or corresponding interface circuitry, as discussed above). The GPS device 2422 may be in communication with a satellite-based system and may receive a location of the computing device 2400, as known in the art.

The computing device 2400 may include a security interface device 2424. The security interface device 2424 may include any device that provides security features for the computing device 2400 or for any individual components therein (e.g., for the processing device 2402 or for the memory 2404). Examples of security features may include authorization, access to digital certificates, access to items in keychains, etc. Examples of the security interface device 2424 may include a software firewall, a hardware firewall, an antivirus, a content filtering device, or an intrusion detection device.

In some embodiments, the computing device 2400 may include a temperature detection device 2426 and a temperature regulation device 2428.

The temperature detection device 2426 may include any device capable of determining temperatures of the computing device 2400 or of any individual components therein (e.g., temperatures of the processing device 2402 or of the memory 2404). In various embodiments, the temperature detection device 2426 may be configured to determine temperatures of an object (e.g., the computing device 2400, components of the computing device 2400, devices coupled to the computing device, etc.), temperatures of an environment (e.g., a data center that includes, is controlled by, or otherwise associated with the computing device 2400), and so on. The temperature detection device 2426 may include one or more temperature sensors. Different temperature sensors of the temperature detection device 2426 may have different locations within and around the computing device 2400. A temperature sensor may generate data (e.g., digital data) representing detected temperatures and provide the data to another device, e.g., to the temperature regulation device 2428, the processing device 2402, the memory 2404, etc. In some embodiments, a temperature sensor of the temperature detection device 2426 may be turned on or off, e.g., by the processing device 2402 or an external system. The temperature sensor detects temperatures when it is on and does not detect temperatures when it is off. In other embodiments, a temperature sensor of the temperature detection device 2426 may detect temperatures continuously and automatically or detect temperatures at predefined times or at times triggered by an event associated with the computing device 2400 or any components therein.

The temperature regulation device 2428 may include any device configured to change (e.g., decrease) temperatures, e.g., based on one or more target temperatures and/or based on temperature measurements performed by the temperature detection device 2426. A target temperature may be a preferred temperature. A target temperature may depend on a setting in which the computing device 2400 operates. In some embodiments, the target temperature may be 200 Kelvin degrees or lower. In some embodiments, the target temperature may be 20 Kelvin degrees or lower, or 5 Kelvin degrees or lower. Target temperatures for different objects and different environments of, or associated with, the computing device 2400 can be different. In some embodiments, cooling provided by the temperature regulation device 2428 may be a multi-stage process with temperatures ranging from room temperature to 4K or lower.

In some embodiments, the temperature regulation device 2428 may include one or more cooling devices. Different cooling device may have different locations within and around the computing device 2400. A cooling device of the temperature regulation device 2428 may be associated with one or more temperature sensors of the temperature detection device 2426 and may be configured to operate based on temperatures detected the temperature sensors. For instance, a cooling device may be configured to determine whether a detected ambient temperature is above the target temperature or whether the detected ambient temperature is higher than the target temperature by a predetermined value or determine whether any other temperature-related condition associated with the temperature of the computing device 2400 is satisfied. In response to determining that one or more temperature-related condition associated with the temperature of the computing device 2400 are satisfied (e.g., in response to determining that the detected ambient temperature is above the target temperature), a cooling device may trigger its cooling mechanism and start to decrease the ambient temperature. Otherwise, the cooling device does not trigger any cooling. A cooling device of the temperature regulation device 2428 may operate with various cooling mechanisms, such as evaporation cooling, radiation cooling, conduction cooling, convection cooling, other cooling mechanisms, or any combination thereof. A cooling device of the temperature regulation device 2428 may include a cooling agent, such as a water, oil, liquid nitrogen, liquid helium, etc. In some embodiments, the temperature regulation device 2428 may be, for example, a dilution refrigerator, a helium-3 refrigerator, or a liquid helium refrigerator. In some embodiments, the temperature regulation device 2428 or any portions thereof (e.g., one or more of the individual cooling devices) may be connected to the computing device 2400 in close proximity (e.g., less than about 1 meter) or may be provided in a separate enclosure where a dedicated heat exchanger (e.g., a compressor, a heating, ventilation, and air conditioning (HVAC) system, liquid helium, liquid nitrogen, etc.) may reside.

By maintaining the target temperatures, the energy consumption of the computing device 2400 (or components thereof) can be reduced, while the computing efficiency may be improved. For example, when the computing device 2400 (or components thereof) operates at lower temperatures, energy dissipation (e.g., heat dissipation) may be reduced. Further, energy consumed by semiconductor components (e.g., energy needed for switching transistors of any of the components of the computing device 2400) can also be reduced. Various semiconductor materials may have lower resistivity and/or higher mobility at lower temperatures. That way, the electrical current per unit supply voltage may be increased by lowering temperatures. Conversely, for the same current that would be needed, the supply voltage may be lowered by lowering temperatures. As energy corelates to the supply voltage, the energy consumption of the semiconductor components may lower too. In some implementations, the energy savings due to reducing heat dissipation and reducing energy consumed by semiconductor components of the computing device or components thereof may outweigh (sometimes significantly outweigh) the costs associated with energy needed for cooling.

The computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2400 may be any other electronic device that processes data.

FIG. 7 is a block diagram of an example processing device 2500 that may include an IC structure with one or more vias connected to bonding pads in accordance with any of the embodiments disclosed herein. For example, any suitable ones of the components of the processing device 2500 may include a die (e.g., the die 2002 of FIG. 3) having one or more IC structures with one or more vias connected to bonding pads as described herein. Any one or more of the components of the processing device 2500 may include, or be included in, an IC device 2300 (FIG. 5). Any one or more of the components of the processing device 2500 may include, or be included in, an IC package 2200 of FIG. 4 or an IC device 2300 of FIG. 5. Any one or more of the components of the processing device 2500 may include, or be included in, a computing device 2400 of FIG. 6; for example, the processing device 2500 may be the processing device 2402 of the computing device 2400.

A number of components are illustrated in FIG. 7 as included in the processing device 2500, but any one or more of these components may be omitted or duplicated, as suitable for the application. In some embodiments, some or all of the components included in the processing device 2500 may be attached to one or more motherboards. In some embodiments, some or all of these components are fabricated on a single SoC die or coupled to a single support structure, e.g., to a single carrier substrate.

Additionally, in various embodiments, the processing device 2500 may not include one or more of the components illustrated in FIG. 7, but the processing device 2500 may include interface circuitry for coupling to the one or more components. For example, the processing device 2500 may not include a memory 2504, but may include display device interface circuitry (e.g., a connector and driver circuitry) to which a memory 2504 may be coupled.

The processing device 2500 may include logic circuitry 2502 (e.g., one or more circuits configured to implement logic/compute functionality). Examples of such circuits include ICs implementing one or more of input/output (I/O) functions, arithmetic operations, pipelining of data, etc.

In some embodiments, the logic circuitry 2502 may include one or more circuits responsible for read/write operations with respect to the data stored in the memory 2504. To that end, the logic circuitry 2502 may include one or more I/O ICs configured to control access to data stored in the memory 2504.

In some embodiments, the logic circuitry 2502 may include one or more high-performance compute dies, configured to perform various operations with respect to data stored in the memory 2504 (e.g., arithmetic and logic operations, pipelining of data from one or more memory dies of the memory 2504, and possibly also data from external devices/chips). In some embodiments, the logic circuitry 2502 may be configured to only control I/O access to data but not perform any operations on the data. In some embodiments, the logic circuitry 2502 may implement ICs configured to implement I/O control of data stored in the memory 2504, assemble data from the memory 2504 for transport (e.g., transport over a central bus) to devices/chips that are either internal or external to the processing device 2500, etc. In some embodiments, the logic circuitry 2502 may not be configured to perform any operations on the data besides I/O and assembling for transport to the memory 2504.

The processing device 2500 may include a memory 2504, which may include one or more ICs configure to implement memory circuitry (e.g., ICs implementing one or more of memory devices, memory arrays, control logic configured to control the memory devices and arrays, etc.). In some embodiments, the memory 2504 may be implemented substantially as described above with reference to the memory 2404 (FIG. 6). In some embodiments, the memory 2504 may be a designated device configured to provide storage functionality for the components of the processing device 2500 (e.g., local), while the memory 1604 may be configured to provide system-level storage functionality for the entire computing device 2400 (e.g., global). In some embodiments, the memory 2504 may include memory that shares a die with the logic circuitry 2502.

In some embodiments, the memory 2504 may include a flat memory (also sometimes referred to as a “flat hierarchy memory” or a “linear memory”) and, therefore, may also be referred to as a “basin memory.” As known in the art, a flat memory or a linear memory refers to a memory addressing paradigm in which memory may appear to the program as a single contiguous address space, where a processor can directly and linearly address all of the available memory locations without having to resort to memory segmentation or paging schemes. Thus, the memory implemented in the memory 2504 may be a memory that is not divided into hierarchical layer or levels in terms of access of its data.

In some embodiments, the memory 2504 may include a hierarchical memory. In this context, hierarchical memory refers to the concept of computer architecture where computer storage is separated into a hierarchy based on features of memory such as response time, complexity, capacity, performance, and controlling technology. Designing for high performance may require considering the restrictions of the memory hierarchy, e.g., the size and capabilities of each component. With hierarchical memory, each of the various memory components can be viewed as part of a hierarchy of memories (m₁, m₂, . . . , mₙ) in which each member mi is typically smaller and faster than the next highest member mi+1 of the hierarchy. To limit waiting by higher levels, a lower level of a hierarchical memory structure may respond by filling a buffer and then signaling for activating the transfer. For example, in some embodiments, the hierarchical memory implemented in the memory 2504 may be separated into four major storage levels: 1) internal storage (e.g., processor registers and cache), 2) main memory (e.g., the system RAM and controller cards), and 3) on-line mass storage (e.g., secondary storage), and 4) off-line bulk storage (e.g., tertiary, and off-line storage). However, as the number of levels in the memory hierarchy and the performance at each level has increased over time and is likely to continue to increase in the future, this example hierarchical division provides only one non-limiting example of how the memory 2504 may be arranged.

The processing device 2500 may include a communication device 2506, which may be implemented substantially as described above with reference to the communication chip 2406 (FIG. 6). In some embodiments, the communication device 2506 may be a designated device configured to provide communication functionality for the components of the processing device 2500 (e.g., local), while the communication chip 2406 may be configured to provide system-level communication functionality for the entire computing device 2400 (e.g., global).

The processing device 2500 may include interconnects 2508, which may include any element or device that includes an electrically conductive material for providing electrical connectivity to one or more components of, or associated with, a processing device 2500 or/and between various such components. Examples of the interconnects 2508 include conductive lines/wires (also sometimes referred to as “lines” or “metal lines” or “trenches”) and conductive vias (also sometimes referred to as “vias” or “metal vias”), metallization stacks, redistribution layers, MIM structures, etc.

The processing device 2500 may include a temperature detection device 2510 which may be implemented substantially as described above with reference to the temperature detection device 2426 of FIG. 6 but configured to determine temperatures on a more local scale, e.g., of the processing device 2500 of components thereof. In some embodiments, the temperature detection device 2510 may be a designated device configured to provide temperature detection functionality for the components of the processing device 2500 (e.g., local), while the temperature detection device 2426 may be configured to provide system-level temperature detection functionality for the entire computing device 2400 (e.g., global).

The processing device 2500 may include a temperature regulation device 2512 which may be implemented substantially as described above with reference to the temperature regulation device 2428 of FIG. 6 but configured to regulate temperatures on a more local scale, e.g., of the processing device 2500 of components thereof. In some embodiments, the temperature regulation device 2512 may be a designated device configured to provide temperature regulation functionality for the components of the processing device 2500 (e.g., local), while the temperature regulation device 2428 may be configured to provide system-level temperature regulation functionality for the entire computing device 2400 (e.g., global).

The processing device 2500 may include a battery/power circuitry 2514 which may be implemented substantially as described above with reference to the battery/power circuitry 2410 of FIG. 6. In some embodiments, the battery/power circuitry 2514 may be a designated device configured to provide battery/power functionality for the components of the processing device 2500 (e.g., local), while the battery/power circuitry 2410 may be configured to provide system-level battery/power functionality for the entire computing device 2400 (e.g., global).

The processing device 2500 may include a hardware security device 2516 which may be implemented substantially as described above with reference to the security interface device 2424 of FIG. 6. In some embodiments, the hardware security device 2516 may be a physical computing device configured to safeguard and manage digital keys, perform encryption and decryption functions for digital signatures, authentication, and other cryptographic functions. In some embodiments, the hardware security device 2516 may include one or more secure cryptoprocessors chips.

The following paragraphs provide various examples of the embodiments disclosed herein.

Example 1 provides an IC structure that includes a first layer including a plurality of transistors; a second layer including a stack of layers of one or more insulator materials and conductive interconnect structures extending through the one or more insulator materials; a third layer including bonding pads, where the second layer is between the first layer and the third layer; and a via continuously extending between one of the bonding pads and one of the conductive interconnect structures in a bottom layer of the stack of layers or a conductive structure in the first layer, where the bottom layer is a layer of the stack of layers that is closer to the first layer than all other layers of the stack of layers.

Example 2 provides the IC structure according to example 1, where: the via includes an electrically conductive material, a first end, and a second end, the second end is opposite the first end, a portion of the electrically conductive material at the first end of the via is in conductive contact with the one of the conductive interconnect structures in the bottom layer of the stack of layers or with the conductive structure in the first layer, and a portion of the electrically conductive material at the second end of the via is in conductive contact with the one of the bonding pads.

Example 3 provides the IC structure according to example 2, where a width of the via at the first end is larger than a width of the via at the second end.

Example 4 provides the IC structure according to example 3, where a width of the via continuously increases from the first end of the via to the second end of the via.

Example 5 provides the IC structure according to example 2, where a width of the via at the second end is larger than a width of the via at the first end.

Example 6 provides the IC structure according to any one of examples 1-5, where the one of the bonding pads has a first end and a second end opposite the first end, the first end of the one of the bonding pads is closer to the second layer than the second end of the one of the bonding pads, and a width of the one of the bonding pads at the first end is larger than a width of the one of the bonding pads at the second end.

Example 7 provides the IC structure according to any one of examples 1-5, where the one of the bonding pads has a first end and a second end opposite the first end, the first end of the one of the bonding pads is closer to the second layer than the second end of the one of the bonding pads, and a width of the one of the bonding pads at the second end is larger than a width of the one of the bonding pads at the first end.

Example 8 provides the IC structure according to any one of the preceding examples, further including a bonding layer between the first layer and the second layer.

Example 9 provides the IC structure according to example 8, where the bonding layer includes silicon, nitrogen, and carbon, where an atomic percentage of each of silicon, nitrogen, and carbon is at least 1%.

Example 10 provides the IC structure according to examples 8 or 9, where the bonding layer includes direct bonding interconnects.

Example 11 provides the IC structure according to any one of the preceding examples, further including a bonding layer between the second layer and the third layer.

Example 12 provides the IC structure according to example 11, where the bonding layer includes silicon, nitrogen, and carbon, where an atomic percentage of each of silicon, nitrogen, and carbon is at least 1%.

Example 13 provides the IC structure according to examples 11 or 12, where the bonding layer includes direct bonding interconnects.

Example 14 provides the IC structure according to any one of the preceding examples, where the third layer further includes a solder resist material around the bonding pads.

Example 15 provides the IC structure according to any one of the preceding examples, where a pitch of the bonding pads is between about 10 micron and about 20 micron.

Example 16 provides the IC structure according to any one of the preceding examples, where a pitch of the conductive interconnect structures in the bottom layer is less than 0.5 micron.

Example 17 provides a method of fabricating an IC structure, the method including providing a first layer including a plurality of transistors; providing a second layer including a stack of layers of one or more insulator materials and conductive interconnect structures extending through the one or more insulator materials; providing a third layer including bonding pads, where the second layer is between the first layer and the third layer; and providing a via continuously extending between one of the bonding pads and one of the conductive interconnect structures in a bottom layer of the stack of layers or a conductive structure in the first layer, where the bottom layer is a layer of the stack of layers that is closer to the first layer than all other layers of the stack of layers.

Example 18 provides the method according to example 17, where: the via includes an electrically conductive material, a first end, and a second end, the second end is opposite the first end, a portion of the electrically conductive material at the first end of the via is in conductive contact with the one of the conductive interconnect structures in the bottom layer of the stack of layers or with the conductive structure in the first layer, and a portion of the electrically conductive material at the second end of the via is in conductive contact with the one of the bonding pads.

Example 19 provides an IC package that includes an IC structure according to any one of the preceding examples; and a further component, coupled to the IC structure. For example, the IC structure may include a device layer comprising a plurality of active IC components; a bonding pads layer comprising bonding pads; a metallization stack comprising a stack of metal layers between the device layer and the bonding pads layer; and a via having a first end directly connected to one of the plurality of active IC components and having a second end directly connected to one of the bonding pads, the via extending through the metallization stack.

Example 20 provides the IC package according to example 19, where the further component is or includes one of a package substrate, an interposer, or a further IC die.

In various further examples of the IC package according to examples 19 or 20, the further component may be coupled to the IC die via one or more first-level interconnects, where the one or more first-level interconnects may include one or more solder bumps, solder posts, or bond wires.

In further examples of the IC package according to any of the preceding examples, the IC die includes, or is a part of, at least one of a memory device, a computing device, a wearable device, a handheld electronic structure, and a wireless communications device.

Example 21 provides an electronic structure that includes a carrier substrate; and one or more of the IC structure according to any one of the preceding examples and the IC package according to any one of the preceding examples, coupled to the carrier substrate.

Example 22 provides the electronic structure according to example 21, where the carrier substrate is a motherboard.

Example 23 provides the electronic structure according to example 21, where the carrier substrate is a PCB.

Example 24 provides the electronic structure according to any one of examples 21-23, where the electronic structure is a wearable electronic structure (e.g., a smart watch) or handheld electronic structure (e.g., a mobile phone).

Example 25 provides the electronic structure according to any one of examples 21-24, where the electronic structure further includes one or more communication chips and an antenna.

Example 26 provides the electronic structure according to any one of examples 21-25, where the electronic structure is a memory device.

Example 27 provides the electronic structure according to any one of examples 21-25, where the electronic structure is one of an RF transceiver, a switch, a power amplifier, a low-noise amplifier, a filter, a filter bank, a duplexer, an upconverter, or a downconverter of an RF communications device, e.g., of an RF transceiver.

Example 28 provides the electronic structure according to any one of examples 21-25, where the electronic structure is a computing device.

Example 29 provides the electronic structure according to any one of examples 21-28, where the electronic structure is included in a base station of a wireless communication system.

Example 30 provides the electronic structure according to any one of examples 21-28, where the electronic structure is included in a user equipment device (i.e., a mobile device) of a wireless communication system.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) structure, comprising:
a first layer comprising a plurality of transistors;
a second layer comprising a stack of layers of one or more insulator materials and conductive interconnect structures extending through the one or more insulator materials;
a third layer comprising bonding pads, wherein the second layer is between the first layer and the third layer; and
a via continuously extending between one of the bonding pads and one of the conductive interconnect structures in a bottom layer of the stack of layers or a conductive structure in the first layer,
wherein the bottom layer is a layer of the stack of layers that is closer to the first layer than all other layers of the stack of layers.

2. The IC structure according to claim 1, wherein:
the via includes an electrically conductive material, a first end, and a second end,
the second end is opposite the first end,
a portion of the electrically conductive material at the first end of the via is in conductive contact with the one of the conductive interconnect structures in the bottom layer of the stack of layers or with the conductive structure in the first layer, and
a portion of the electrically conductive material at the second end of the via is in conductive contact with the one of the bonding pads.

3. The IC structure according to claim 2, wherein a width of the via at the first end is larger than a width of the via at the second end.

4. The IC structure according to claim 3, wherein a width of the via continuously increases from the first end of the via to the second end of the via.

5. The IC structure according to claim 2, wherein a width of the via at the second end is larger than a width of the via at the first end.

6. The IC structure according to claim 1, wherein the one of the bonding pads has a first end and a second end opposite the first end, the first end of the one of the bonding pads is closer to the second layer than the second end of the one of the bonding pads, and a width of the one of the bonding pads at the first end is larger than a width of the one of the bonding pads at the second end.

7. The IC structure according to claim 1, wherein the one of the bonding pads has a first end and a second end opposite the first end, the first end of the one of the bonding pads is closer to the second layer than the second end of the one of the bonding pads, and a width of the one of the bonding pads at the second end is larger than a width of the one of the bonding pads at the first end.

8. The IC structure according to claim 1, further comprising a bonding layer between the first layer and the second layer.

9. The IC structure according to claim 8, wherein the bonding layer includes silicon, nitrogen, and carbon, where an atomic percentage of each of silicon, nitrogen, and carbon is at least 1%.

10. The IC structure according to claim 8, wherein the bonding layer includes direct bonding interconnects.

11. The IC structure according to claim 1, further comprising a bonding layer between the second layer and the third layer.

12. The IC structure according to claim 11, wherein the bonding layer includes silicon, nitrogen, and carbon, where an atomic percentage of each of silicon, nitrogen, and carbon is at least 1%.

13. The IC structure according to claim 11, wherein the bonding layer includes direct bonding interconnects.

14. The IC structure according to claim 1, wherein the third layer further includes a solder resist material around the bonding pads.

15. The IC structure according to claim 1, wherein a pitch of the bonding pads is between about 10 micron and about 20 micron.

16. The IC structure according to claim 1, wherein a pitch of the conductive interconnect structures in the bottom layer is less than 0.5 micron.

17. A method of fabricating an integrated circuit (IC) structure, the method comprising:
providing a first layer comprising a plurality of transistors;
providing a second layer comprising a stack of layers of one or more insulator materials and conductive interconnect structures extending through the one or more insulator materials;
providing a third layer comprising bonding pads, wherein the second layer is between the first layer and the third layer; and
providing a via continuously extending between one of the bonding pads and one of the conductive interconnect structures in a bottom layer of the stack of layers or a conductive structure in the first layer,
wherein the bottom layer is a layer of the stack of layers that is closer to the first layer than all other layers of the stack of layers.

18. The method according to claim 17, wherein:
the via includes an electrically conductive material, a first end, and a second end,
the second end is opposite the first end,
a portion of the electrically conductive material at the first end of the via is in conductive contact with the one of the conductive interconnect structures in the bottom layer of the stack of layers or with the conductive structure in the first layer, and
a portion of the electrically conductive material at the second end of the via is in conductive contact with the one of the bonding pads.

19. An integrated circuit (IC) package, comprising:
an IC die, comprising an IC structure; and
a further component, coupled to the IC die,
wherein the IC structure includes: a device layer comprising a plurality of active IC components, a bonding pads layer comprising bonding pads, a metallization stack comprising a stack of metal layers between the device layer and the bonding pads layer, and a via having a first end directly connected to one of the plurality of active IC components and having a second end directly connected to one of the bonding pads, the via extending through the metallization stack.

20. The IC package according to claim 19, wherein the further component is one of a package substrate, an interposer, or a further IC die.
